(19) United States
(12) Patent Application Publication
(10) Pub. No.: US 2002/0033527 A1
(43) Pub. Date: Mar. 21, 2002

(54) Semiconductor device and manufacturing process thereof

(75) Inventors: Chien-Ping Huang, Hsinchu (TW); Jui-Meng Jao, Miaoli (TW)

Correspondence Address: Mr. Peter F. Corless, EDWARDS & ANGELL, LLP, Dike, Bronstein, Roberts & Cushman, IP Group, 101 Federal Street, Boston, MA, 02110, US

(73) Assignee: Siliconware precision Industries Co., Ltd.

(21) Appl. No.: 09/908,191

(22) Filed: Jul. 18, 2001

(30) Foreign Application Priority Data
Sep. 19, 2000 (TW) 89119258

(51) Int. Cl. H01L 23/22

(52) U.S. Cl. 257/687; 257/738; 257/787

(57) ABSTRACT

A semiconductor device and a manufacturing process thereof are proposed. With no use of a substrate or leads, the foregoing semiconductor device has a chip with its surfaces being exposed to the outside of the device, allowing the overall thickness of the device to be significantly minimized, and the heat-dissipating efficiency to be greatly improved, as well as the manufacturing process and cost to be simplified and reduced respectively. Moreover, unlike a conventional semiconductor device, the semiconductor device is manufactured without using a specific mold with protrusions, a drill or a laser beam, so that the manufacturing cost is further reduced, and crack in the encapsulant as well as flash during molding are prevented.

### FIELD OF THE INVENTION

The present invention relates to semiconductor devices and manufacturing processes thereof, and, more particularly, to a semiconductor device and a manufacturing process thereof, which can ulitize solder balls for electrically connecting a semiconductor chip to external devices.

### BACKGROUND OF THE INVENTION

A ball grid array (BGA) semiconductor device is disclosed by U.S. Pat. No. 5,216,278, wherein a substrate thereof having its both sides respectively mounted with a semiconductor chip and solder balls is relatively complex in structure and accordingly has a rather large thickness. As a result, the foregoing substrate is cost-ineffective to fabricate, and is not suitably applied to minimized electronic products.

Therefore, U.S. Pat. No. 5,663,594 proposes a BGA semiconductor device having a lead frame instead of the foregoing thick and expensive substrate, allowing solder balls to be directly bonded onto leads of the lead frame. Such a BGA semiconductor device 1, as illustrated in FIG. 1, includes a semiconductor chip 10 having a first surface 10A and a second surface 10B; a plurality of leads 11 each having a first surface 11A and a second surface 11B, and extending inwardly in parallel; bonding wires 12 such as gold wires each having two ends respectively bonded to the first surface 10A of the chip 10 and the first surface 11A of the corresponding lead 11 for electrically connecting the chip 10 to the leads 11; an encapsulant 13 for encapsulating the chip 10, the lead frame 11 and the bonding wires 12 therein; and a plurality of solder balls 14 formed on the encapsulant 13 and connected through a plurality of holes 13B to the second surface 11B of the corresponding leads 11, wherein the chip 10 is connected to inside portions of the first surface 11A of the leads 11 through an insulating tape 15 attached to the second surface 10B of the chip 10.

The manufacturing process for the foregoing BGA semiconductor device 1 includes the following steps. First, a lead frame 110 having a plurality of leads 11 extending inwardly in parallel is provided, as shown in FIG. 2A. Thereafter, a semiconductor chip 10 is attached to inside portions of the leads 11 by means of an insulating tape, as shown in FIG. 2B. Then, bonding wires 12 are bonded to a first surface 10A of the chip 10 and a first surface 11A of the corresponding leads 11 respectively. An encapsulant 13 is formed to encapsulate the chip 10, the leads 11 and the bonding wires 12, and on the cured encapsulant 13 there are formed a plurality of holes 13B for being respectively connected to a second surface 11B of the corresponding leads 11, as shown in FIG. 2C. The holes 13B can also be formed by using a drill or a laser beam corresponding to the size and position of the holes 13B. Next, solder balls 14 such as tin or gold balls are implanted on the holes 13B, and a singulating process is performed to form individual lead frames 110 with a portion of each lead 11 extending out of the encapsulant 13 being retained, as shown in FIG. 2D. The exposed portions of the leads 11 are used for an electric test and then removed after completing the test. As a result, the BGA semiconductor device 1 in FIG. 1 is completed in fabrication without using a substrate, allowing the overall thickness of the device 1 to be minimized and the manufacturing cost to be reduced.

In the formation of the foregoing holes 13B, however, crack may be generated in the encapsulant when drilling the encapsulant with the driller, which may also produce dust as to pollute the working environment, so that quality of products may be degraded, and the dust left in the holes thereby increases difficulty in implanting the solder balls.

On the other hand, using the laser beam for forming the holes 13B eliminates the drawbacks of generating the crack or dust, however, the laser beam is expensive in purchase and maintenance, which makes the BGA device 1 cost-ineffective to fabricate.

Similarly, with the use of the resin mold having the protrusions for making the holes 13B, besides increase in the cost in purchase and maintenance, flash occurs at positions on the second surface 11B of the leads 11 corresponding to the holes 13B, due to ineffective clamping between the protrusions of the resin mold and the leads 11. As a result, after finishing molding, a deflash process must be performed for removing the flash by using a drill, a laser beam or a chemical solvent, so as to facilitate the implantation of the solder balls. This not only makes the manufacturing process more complicated but increases the manufacturing cost.

Moreover, the encapsulant 13 on both the first and second surfaces of the chip 10 makes the BGA device 1 hard to be minimized in thickness. Besides, if the a high-performance chip is provided in the device 1 having a fixed heat-dissipating path, heat generated by the chip in operation will not be easily dissipated to the atmosphere rapidly and effectively, and thus the lifetime of products will be reduced as well as reliability and credibility of the products will be degraded.

### SUMMARY OF THE INVENTION

A primary objective of the present invention is to provide a semiconductor device and a manufacturing process thereof, which can lower the manufacturing cost and minimize the entire thickness of the semiconductor device. Moreover, The invention can simplify the manufacturing process for the semiconductor device and prevent crack or flash from occurrence, as well as improve the heat-dissipating efficiency of the semiconductor device.

According to the foregoing and other objectives, the semiconductor device of the invention includes: a semiconductor chip having a first surface and a second surface; an encapsulant for encapsulating the chip with the second surface of the chip being exposed to the outside of the encapsulant, wherein the encapsulant is formed with a plurality of recesses around the second surface of the chip, and on an innermost end of each recess there is formed a metal layer for being electrically connected to the first surface of the chip; and a plurality of solder balls respectively implanted at the recesses.

A manufacturing process for the foregoing semiconductor device includes the steps of: providing a metal plate having a first surface and a second surface; plating a metal layer, such as nickel, gold or silver, on part of the first surface of the metal plate, wherein the metal layer is partially used for implanting solder balls thereon and is partially not encapsulated by an encapsulant, partially etching the metal plate by using the metal layer as a mask for forming concaves on the first surface of the metal plate excluding the part of the metal plate being covered by the metal layer; placing a semiconductor chip having a first surface and a second surface on the concave predefined by part of the metal layer used for implanting the solder balls, and allowing the second surface of the chip to be attached to a surface of the concave, electrically connecting the first surface of the chip to the metal layer corresponding to positions for implanting the solder balls; forming an encapsulant to encapsulate the chip; removing the metal plate and the metal layer not being encapsulated by the encapsulant for exposing the second surface of the chip to the outside of the encapsulant, and forming a plurality of recesses on the positions for implanting the solder halls around the second surface of the chip, wherein innermost ends of the recesses are disposed with the metal layer being electrically connected to the chip;, and respectively implanting a plurality of solder balls at the recesses.

Therefore, the semiconductor device of the invention and the manufacturing process thereof only needs to use a conventional upper mold with a cavity and a lower mold without a cavity instead of a specific mold having a plurality of protrusions, a drill or a laser beam, so that drawbacks previously depicted in prior arts can be eliminated, for example, the manufacturing cost is reduced, and crack in the encapsulant or dust pollution is prevented as well as a deflash process is eliminated.

Furthermore, unlike a conventional semiconductor device, with no use of a substrate or leads, the semiconductor device of the invention has the clip with its surfaces being exposed to the outside of the device, allowing the overall thickness of the device to be significantly minimized, and the heat-dissipating efficiency to be greatly improved, as well as the manufacturing process and cost to be simplified and reduced respectively.

### BRIEF DESCRIPTION OF THE DRAWINGS

The present invention may best be understood through the following description with reference to the accompanying drawings, in which:

FIG. 1 (PRIOR ART) is a schematic diagram of a conventional BGA semiconductor device without a substrate;

FIGS. 2A-2D (PRIOR ART) are schematic diagrams showing the process for manufacturing the BOA semiconductor device of FIG. 1; and

FIGS. 3A to 3G are schematic diagrams showing the process for manufacturing the semiconductor device of the preferred embodiment according to the present invention.

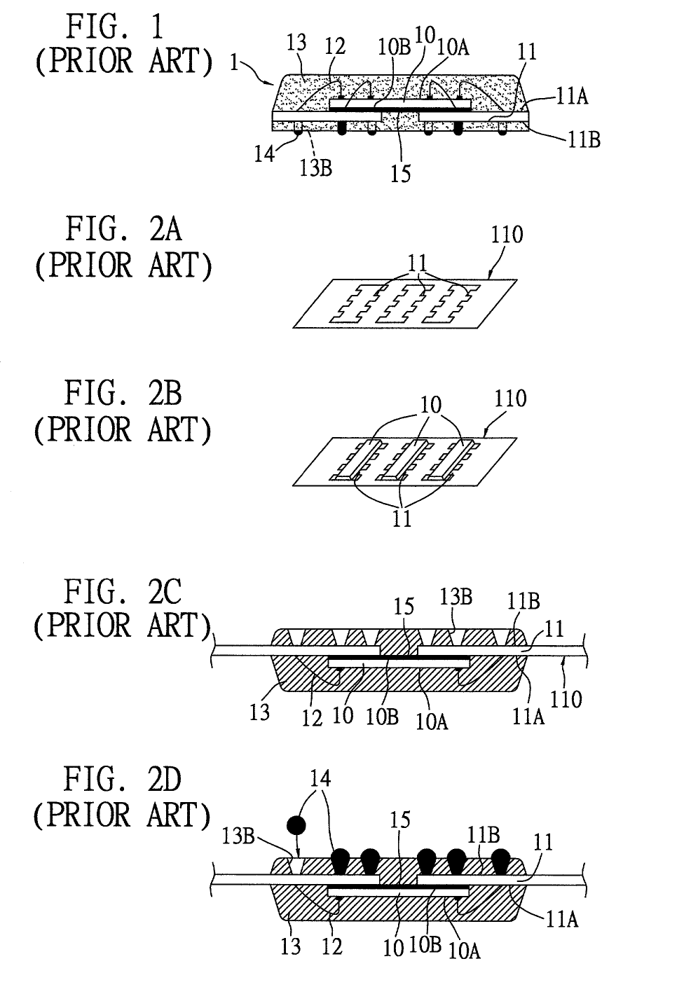

### DETAILED DESCRIPTION OF THE PREFERRED EMBODIMENT

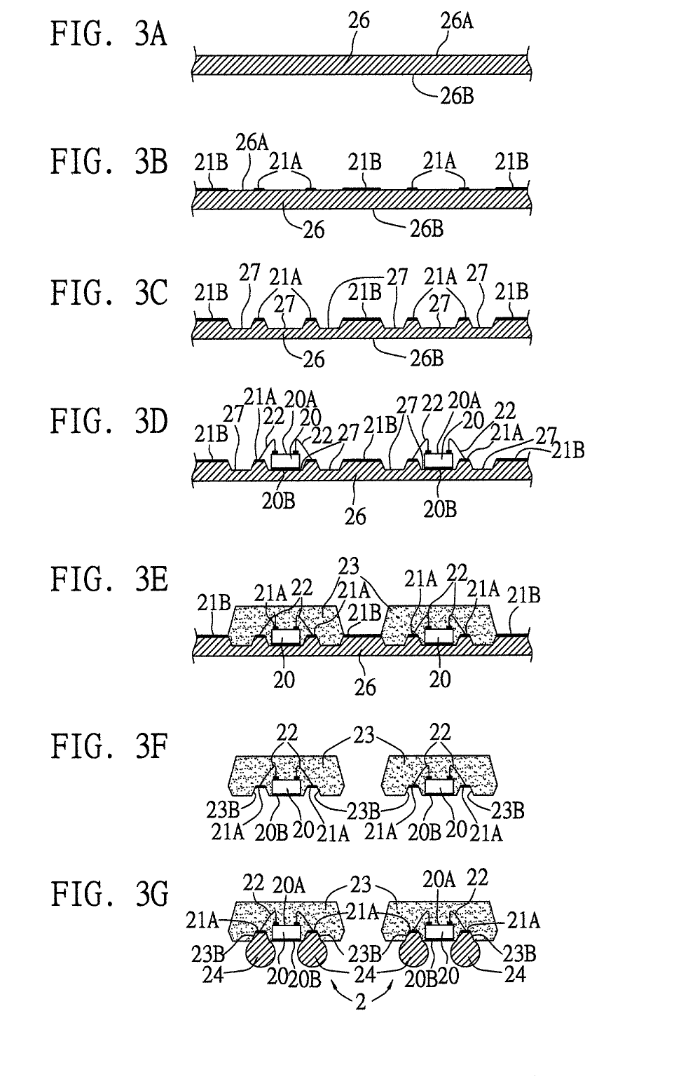

Referring to FIG. 3G, the semiconductor device 2 of the preferred embodiment of the present invention includes: a semiconductor chip 20 having a first surface 20A and a second surface 20B; an encapsulant 23 for encapsulating the chip 20 with the second surface 20B of the chip 20 being exposed to the outside of the encapsulant 23, wherein the encapsulant 23 is formed with a plurality of recesses 23B around the second surface 20B of the chip 20, and on an innermost end of each recess 23B there is formed a metal layer 21A for being electrically connected to the first surface 20A of the chip 20; and a plurality of solder balls 24 such as tin or gold balls respectively implanted at the recesses 23B. The metal layer 21A is electrically connected to the chip 20 through bonding wires 22 such as a gold wire each having two ends bonded to the metal layer 21A and the first surface 20A of the chip 20, respectively.

A manufacturing process for the semiconductor device 2 includes the following steps. First, referring to FIG. 3A, a metal plate 26 having a first surface 26A and a second surface 26B is provided. Then metal layers 21A and 21B are formed by plating a metal such as nickel, gold or silver on part of the first surface 26A of the metal plate 26, wherein the metal layer 21A is used for implanting solder balls thereon, and the metal layer 21B is not encapsulated by an encapsulant, as illustrated in FIG. 3B.

Next, with the use of the metal layers 21A and 21B as a mask, the metal plate 26 is partially etched on the first surface 26A thereof for forming concaves 27 on the metal plate 26 excluding the part thereof being covered by the metal layer, as illustrated in FIG. 3C. Thereafter, a semiconductor chip 20 having a first surface 20A and a second surface 20B is placed on the concave 27 predefined by the metal layer 21A, allowing the second surface 20B of the chip 20 to be attached to a surface of the concave 27. The chip 20 is then electrically connected to the metal layer 21A through bonding wires 22 such as gold wires each having two ends thereof bonded to the metal layer 21A and the first surface 20A of the chip 20, as shown in FIG. 31.

Referring further to FIG. 3E, a molding process is performed to form an encapsulant 23 for encapsulating the chip 20 and the bonding wires 22. During molding, it only requires a conventional upper mold with a cavity and a lower mold with no cavity (not shown), rather than a specific mold having protrusions. Then, the metal plate 26 and the retained metal layer 21B are removed by etching, allowing the second surface 20B of the chip 20 to be exposed to the outside of the encapsulant 23, as well as a plurality of recesses 23B to be formed on the positions for implanting solder balls around the exposed surface 20B of the chip 20, wherein innermost ends of the recesses 23B are disposed with the metal layer 21A being electrically connected to the chip 20, as illustrated in FIG. 3F.

Finally, a plurality of solder balls 24 such as tin or gold balls are respectively implanted at the recesses 23B, so that the fabrication of the semiconductor device 2 is completed, as shown in FIG. 3G.

As concluded from the above mentioned, the semiconductor device of the invention and the manufacturing process thereof eliminates the need of a mold with protrusions specifically used for forming the recesses for solder ball implantation, so that drawbacks previously depicted in prior arts are avoided, for example, the manufacturing cost is reduced, and flash during molding is prevented as well as a deflash process is eliminated.

Furthermore, with no use of a drill or a laser beam in the formation of the recesses in the invention, crack in the encapsulant or dust pollution generated during drilling the encapsulant can be prevented as well as the cost for the laser beam in purchase and maintenance can be saved.

Moreover, unlike a conventional semiconductor device, with no use of a substrate or leads, the semiconductor device of the invention has the chip with its surfaces being exposed to the outside of the device, allowing the overall thickness of the device to be significantly minimized, and the heat-dissipating efficiency to be greatly improved, as well as the manufacturing process and cost to be simplified and reduced respectively.

In addition, the invention has the solder balls implanted in the deep recesses, allowing the solder balls to be tightly clamped by the recesses, so as to eliminate a defect of solder balls being separating from solder pads occurred in a conventional device, wherein the solder balls are merely implanted on the solder pads.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor device, comprising:
a semiconductor chip having a first surface and a second surface,
an encapsulant for encapsulating the semiconductor chip with the second surface of the semiconductor chip being exposed to the outside of the encapsulant, wherein the encapsulant is formed with a plurality of recesses around the second surface of the semiconductor chip, and on an innermost end of each recess there is formed a metal layer for being electrically connected to the first surface of the semiconductor chip; and
a plurality of solder balls implanted at the recesses respectively.

2. The semiconductor device of claim 1, wherein the metal layer is electrically connected to the semiconductor chip through bonding wires each having two ends bonded to the metal layer and the first surface of the semiconductor chip respectively.

3. The semiconductor device of claim 2, wherein the bonding wires are gold wire.

4. The semiconductor device of claim 1, wherein the metal layer is made of nickel.

5. The semiconductor device of claim 1, wherein the metal layer is made of gold.

6. The semiconductor device of claim 1, wherein the metal layer is made of silver.

7. The semiconductor device of claim 1, wherein the solder balls are tin balls.

8. The semiconductor device of claim 1, wherein the solder balls are gold balls.

9. A manufacturing method of a semiconductor device, comprising the steps of:
providing a metal plate having a first surface and a second surface;
plating a first metal layer and a second metal layer on part of the first surface of the metal plate, wherein the first metal layer is used for implanting solder balls thereon, and the second metal layer is formed on area of the metal plate exclusive of an encapsulant;
partially etching the metal plate by using the metal layer as a mask for forming concaves on the first surface of the metal plate excluding area of the metal plate covered by the metal layers;
placing a semiconductor chip having a first surface and a second surface on the concave predefined by the first metal layer for attaching the second surface of the semiconductor chip to a surface of the concave,
electrically connecting the first surface of the chip to the first metal layer;
forming an encapsulant to encapsulate the semiconductor chip;
removing the metal plate and the second metal layer by using a etching process for exposing the second surface of the semiconductor chip to the outside of the encapsulant, and forming a plurality of recesses around the second surface of the semiconductor chip, wherein innermost ends of the recesses are disposed with the first metal layer being electrically connected to the semiconductor chip; and
implanting a plurality of solder balls at the recesses respectively.

10. The manufacturing method of claim 9, wherein the first metal layer is electrically connected to the semiconductor chip through bending wires each having two ends thereof bonded to the first metal layer and the first surface of said semiconductor chip respectively.

11. The manufacturing method of claim 10, wherein the bonding wires are gold wires.

12. The manufacturing method of claim 9, wherein the metal layers are made of nickel.

13. The manufacturing method of claim 9, wherein the metal layers are made of gold.

14. The manufacturing method of claim 9, wherein the metal layers are made of silver.

15. The manufacturing method of claim 9, wherein the solder balls are tin balls.

16. The manufacturing method of claim 9, wherein the solder balls are gold balls.

17. The manufacturing method of claim 9, wherein molds used in the step of forming the encapsulant includes an upper mold with a cavity and a lower mold with no cavity.
